(19) United States
(12) Patent Application Publication
(10) Pub. No.: US 2005/0201067 A1
(43) Pub. Date: Sep. 15, 2005

(54) Electronic device

(76) Inventors: Chih-Kai Hu, Taipei City (TW); Ming-Chang Shih, Keelung City (TW)

Correspondence Address: RABIN & Berdo, PC, 1101 14TH STREET, NW, SUITE 500, WASHINGTON, DC, 20005, US

(21) Appl. No.: 11/067,724

(22) Filed: Mar. 1, 2005

(30) Foreign Application Priority Data
Mar. 12, 2004 (TW) 93106637

(51) Int. Cl. H05K 5/02

(52) U.S. Cl. 361/730; 361/731; 361/732

(57) ABSTRACT

An electronic device. A main body includes a replacement portion and at least one first engaging opening. At least one part of the first engaging opening is formed on the replacement portion. At least one separating member is disposed in the main body. At least one part of the separating member passes through the first engaging opening. At least one replaceable module includes at least one first engaging portion. The replaceable module is fixed in the replacement portion by the first engaging portion engaging the first engaging opening and separates from the replacement portion by means of the separating member.

### BACKGROUND

The invention relates to an electronic device, and in particular to an electronic device with a replaceable module.

When a cellular phone is combined with a PDA to form a conventional PDA phone, keys are disposed on a main body thereof. Generally, the PDA phone includes two independent buttons, one for communication and the other for PDA functions. Accordingly, the PDA phone has multiple buttons and the buttons cannot be shared with each other or be replaceable, thus hindering interoperability in PDA phone.

Hence, there is a need to provide an electronic device with a replaceable module. The replaceable module can be quickly replaced according to operational requirements, thereby enhancing interoperability.

### SUMMARY

Accordingly, an embodiment of the invention provides an electronic device comprising a main body, at least one separating member, and at least one replaceable module. The main body comprises a replacement portion and at least one first engaging opening. One part of the first engaging opening is formed on the replacement portion. The separating member is disposed in the main body and one part of the separating member passes through the first engaging opening. The replaceable module comprises at least one first engaging portion. The replaceable module is fixed on the replacement portion of the main body by the first engaging portion engaging the first engaging opening and separates from the replacement portion by means of the separating member.

The separating member further comprises a button key, a resilient element, and a pushing element connected to the button key. The resilient element is connected to the button key. The resilient element and pushing element are disposed on one side of the button key, and one end of the pushing element abuts the first engaging portion when the button key is pushed.

The resilient element may comprise a spring.

The main body further comprises an accommodating portion and a separating wall disposed between the accommodating portion and the replacement portion. The first engaging opening is formed on the separating wall and connects the replacement portion to the accommodating portion. One part of the separating member is disposed in the accommodating portion. One end of the pushing element passes through the first engaging opening to abut the first engaging portion when the button key is pushed.

The main body further comprises a housing and an opening formed thereon and connected to the accommodating portion. One part of the button key is disposed in the opening. The resilient and pushing elements are disposed in the accommodating portion.

The replacement portion further comprises a first bottom surface, a first sidewall, and a third sidewall. The replaceable module further comprises a second bottom surface, a second sidewall, and a fourth sidewall. The first bottom surface faces the second bottom surface, the first sidewall faces the second sidewall, and the third sidewall faces the fourth sidewall when the replaceable module is fixed in the replacement portion.

The first bottom surface further comprises a second engaging opening. The second bottom surface further comprises a second engaging portion. The second engaging portion engages the second engaging opening when the replaceable module is fixed in the replacement portion.

The third sidewall further comprises a third engaging opening. The fourth sidewall of the replaceable module further comprises a third engaging portion. The third engaging portion engages the third engaging opening when the replaceable module is fixed in the replacement portion.

The main body further comprises a first signal connection portion. The replaceable module further comprises a second signal connection portion opposing the first signal connection portion. The first signal connection portion is electrically connected to the second signal connection portion when the replaceable module is fixed in the replacement portion.

The replaceable module is an operating module for a cellular phone as a keyboard.

The first engaging portion further comprises a resilient arm and a hook. One end of the resilient arm is connected to the replaceable module and another end is connected to the hook. The hook engages the first engaging opening when the replaceable module is fixed in the replacement portion.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1A is a schematic perspective view of the main body of the electronic device according to a first embodiment of the invention;

FIG. 1B is a schematic perspective view of the replaceable module of the electronic device according to a first embodiment of the invention;

FIG. 1C is an enlarged perspective view according to FIG. 1A;

FIG. 1D is a schematic side view according to FIG. 1B;

FIG. 1E is a schematic front view according to FIG. 1B;

FIG. 1F is a partial bottom view according to FIG. 1B;

FIG. 2 is a schematic perspective view of the electronic device according to a first embodiment of the invention;

FIG. 3A is a schematic perspective view of the main body of the electronic device according to a second embodiment of the invention;

FIG. 3B is a schematic perspective view of the replaceable module of the electronic device according to a second embodiment of the invention;

FIG. 3C is a schematic front view according to FIG. 3B;

FIG. 3D is a schematic bottom view according to FIG. 3B;

FIG. 3E is an enlarged perspective view according to FIG. 3A; and

FIG. 4 is a schematic perspective view of the electronic device according to a second embodiment of the invention.

### DETAILED DESCRIPTION

### First Embodiment

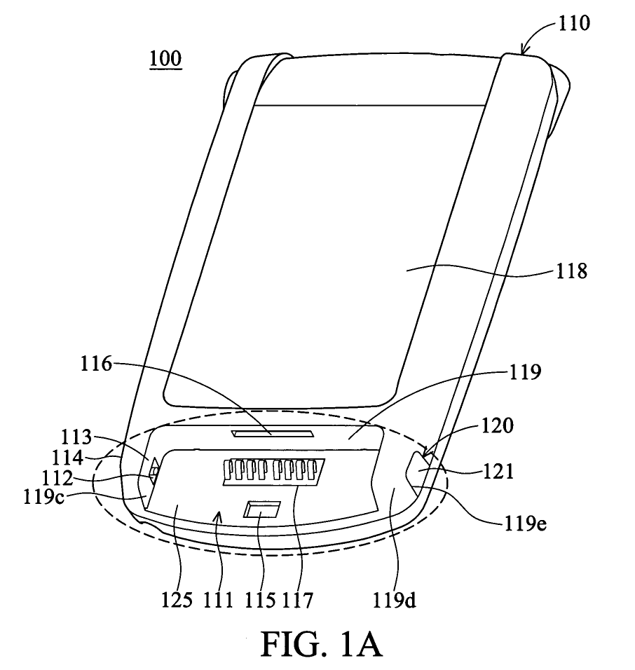

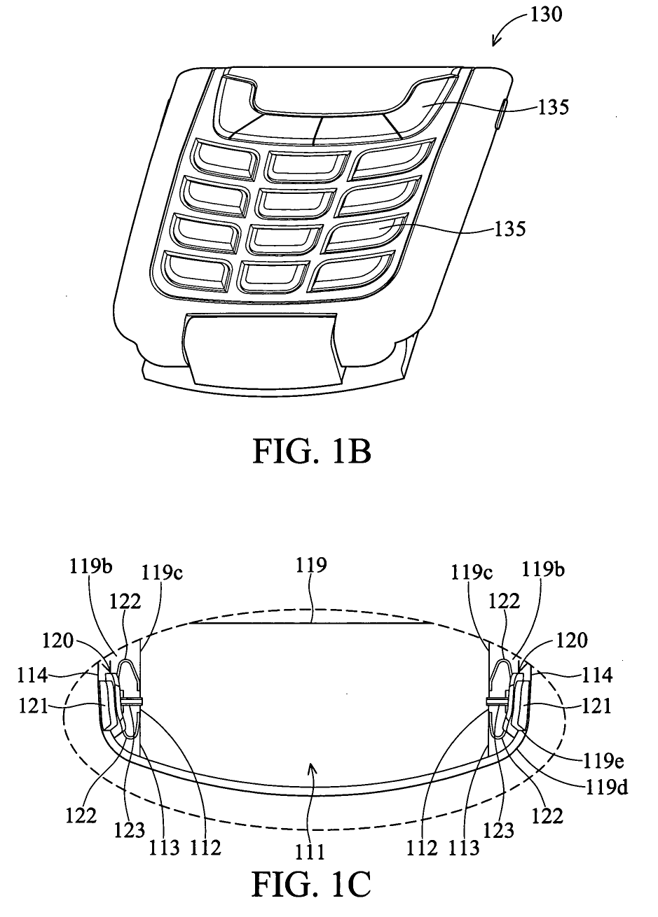

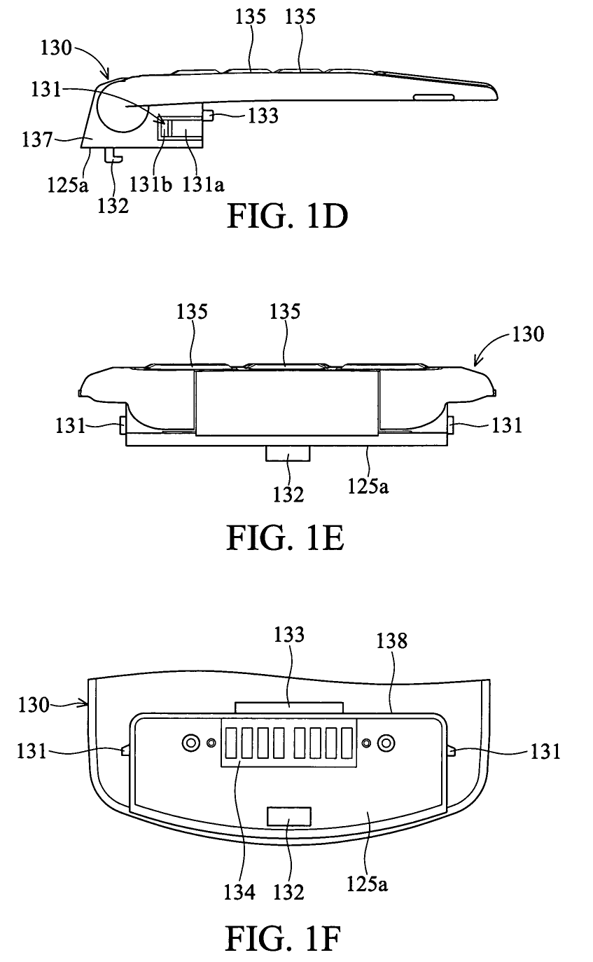

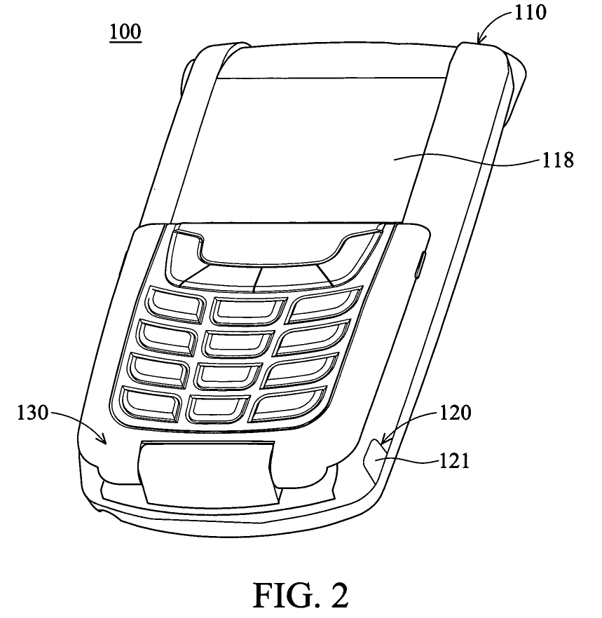

Referring to FIGS. 1A, 1B, and 2, the electronic device 100 comprises a main body 110 and a replaceable module 130. The replaceable module 130, in this embodiment, is an operational module for a cellular phone.

As shown in FIG. 1A and FIG. 1B, the main body 110 comprises a replacement portion 111 and a display 118. The replacement portion 111 is a recess of the main body 110. The replacement portion 111 comprises two opposing first sidewalls 113 with two first engaging openings 112 respectively formed thereon. The display 118 is adjacent to the replacement portion 111. As shown in FIG. 1C, the main body 110 further comprises two accommodating portions 119b and two separating walls 119c. Each separating wall 119c is disposed between each accommodating portion 119b and the replacement portion 111. Each first engaging opening 112 is formed on each separating wall 119c and connects the replacement portion 111 to the corresponding accommodating portion 119b.

Two separating members 120 are disposed in the first engaging openings 112, respectively. Specifically, each separating member 120 is disposed between each first sidewall 113 of the replacement portion 111 and an outer wall 114 of the main body 110. Namely, each separating member 120 is disposed in the corresponding accommodating portion 119b. As shown in FIG. 1C, each separating member 120 comprises a button key 121, two resilient elements 122, and a pushing element 123. The button key 121 is disposed on the outer wall 114 of the main body 110. The resilient elements 122 are disposed between the button key 121 and the first sidewall 113. The pushing element 123 is connected to the button key 121 and corresponds to the first engaging opening 112. As shown in FIG. 1A and FIG. 1C, the main body 110 further comprises a housing 119d and an opening 119e formed thereon and connected to the accommodating portion 119b. At least one part of the button key 121 is disposed in the opening 119e. The resilient elements 122 and pushing element 123 are disposed in the accommodating portion 119b.

Referring to FIGS. 1A, 1C, 1D, and 1E, the replaceable module 130 is detachably disposed in the replacement portion 111 and is electrically connected to the main body 110. Two first engaging portions 131 are disposed on two opposite second sidewalls 137 of the replaceable module 130, respectively. When the replaceable module 130 is fixed in the replacement portion 111, the first engaging portions 131 engage the first engaging openings 112. When the replaceable module 130 is separated from the replacement portion 111, the button keys 121 of the separating members 120 can be simultaneously pushed. The first engaging portions 131 of the replaceable module 130 resiliently retract by abutment of the pushing elements 123 and thereby disengage from the first engaging openings 112. The replaceable module 130 can then be removed from the replacement portion 111. Additionally, as shown in FIG. 1D, each first engaging portion 131 comprises a resilient arm 131a and a hook 131b. One end of the resilient arm 131a is connected to the replaceable module 130 and the other end is connected to the hook 131b. The hook 131b engages the first engaging opening 112 when the replaceable module 130 is fixed in the replacement portion 111.

Moreover, as shown in FIG. 1A, the main body 110 comprises a second engaging opening 115 formed on a first bottom surface 125 of the replacement portion 111. As shown in FIG. 1D, the replaceable module 130 comprises a second engaging portion 132 disposed on a second bottom surface 125a thereof. Namely, the second engaging opening 115 is formed on the bottom of the replacement portion 111 and the second engaging portion 132 is disposed on the bottom of the replaceable module 130. The replaceable module 130 can be fixed on the main body 110 by the second engaging portion 132 engaging the second engaging opening 115.

Moreover, as shown in FIG. 1A, the main body 110 comprises a third engaging opening 116 formed on a third sidewall 119 of the replacement portion 111. As shown in FIG. 1D and FIG. 1F, the replaceable module 130 comprises a third engaging portion 133 formed on a fourth sidewall 138 thereof. The third sidewall 119 is substantially perpendicular to the first sidewalls 113. The replaceable module 130 can be fixed on the main body 110 by the third engaging portion 133 engaging the third engaging opening 116.

Moreover, as shown in FIG. 1A and FIG. 1F, the main body 110 comprises a first signal connection portion 117 and the replaceable module 130 comprises a second signal connection portion 134. Specifically, the first signal connection portion 117 is disposed on the first bottom surface 125 of the main body 110 (as shown in FIG. 1A) and the second signal connection portion 134 is disposed on the second bottom surface 125a of the replaceable module 130 (as shown in FIG. 1F). In some embodiments, the first signal connection portion 117 is a spring plate type connector and the second signal connection portion 134 is a metal connector, i.e. edge connector.

When the replaceable module 130 is fixed on the main body 110, the second engaging portions 132 of the replaceable module 130 can be inserted into the second engaging opening 115 of the replacement portion 111. The replaceable module 130 is then pushed horizontally and toward the third engaging opening 116. Since the second engaging portions 132 have a substantially L-like configuration, the second engaging portions 132 can be engaged in the second engaging opening 115. At this point, the third engaging portion 133 of the replaceable module 130 can enter and engage the third engaging opening 116. In another aspect, the first engaging portions 131 of the replaceable module 130 engage the first engaging openings 112 and the first signal connection portion 117 disposed on the first bottom surface 125 is electrically connected to the second signal connection portion 134 disposed on the second bottom surface 125a of the replaceable module 130. Two-way signal transmission can thus be performed between the replaceable module 130 and the main body 110. Additionally, when the replaceable module 130 is fixed in the replacement portion 111, the first bottom surface 125 faces the second bottom surface 125a, the first sidewalls 113 face the second sidewalls 137, and the third sidewall 119 faces the fourth sidewall 138.

Conversely, when the replaceable module 130 is separated from the main body 110, the button keys 121 of the separating members 120 can be pushed simultaneously. The first engaging portions 131 of the replaceable module 130 resiliently retract by abutment of the pushing elements 123 and thereby disengage from the first engaging openings 112. The replaceable module 130 is pushed horizontally and outward, such that the third engaging portion 133 thereof is separated from the third engaging opening 116 of the replacement portion 111. The replaceable module 130 is then taken up, such that the second engaging portions 132 disposed on the second bottom surface 125a of the replaceable module 130 can be separated from the second engaging opening 115 formed on the replacement portion 111. At this point, the replaceable module 130 is completely removed from the replacement portion 111 or the main body 110 and another replaceable module, such as a computer operation module or a keyboard, can instead be fixed in the replacement portion 111 of the main body 110 as required.

Additionally, as shown in FIG. 1B, the replaceable module 130 comprises a plurality of keys 135 disposed thereon to perform cellular phone functions.

### Second Embodiment

Elements corresponding to those in the first embodiment share the same reference numerals, and explanation thereof is omitted for simplification of the description.

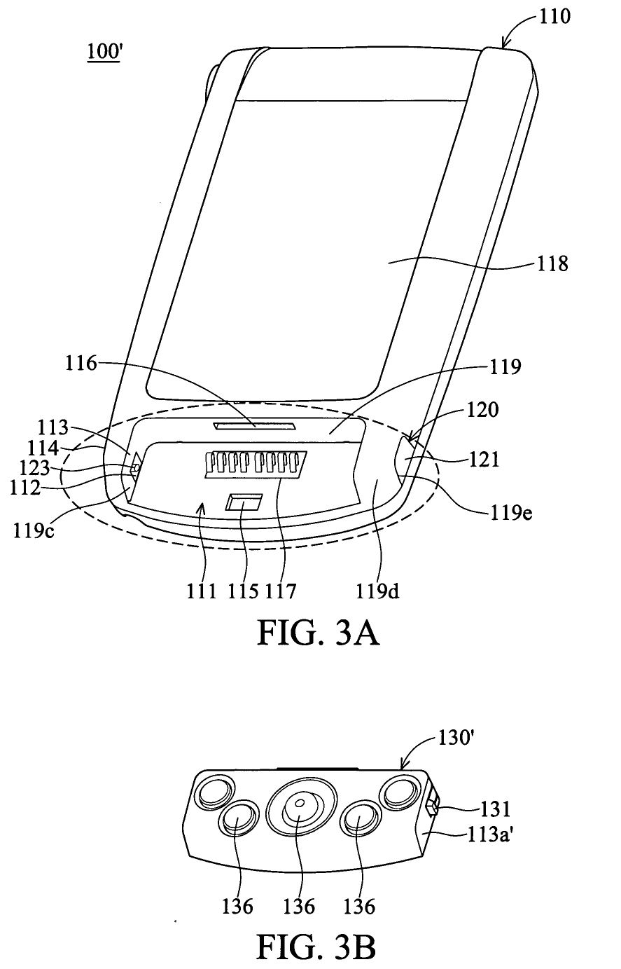

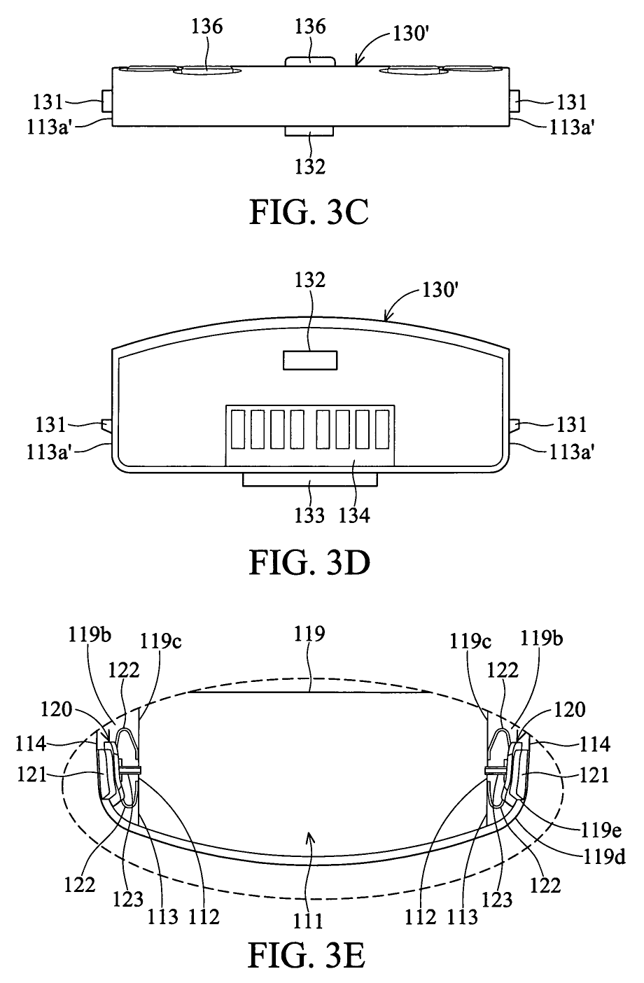

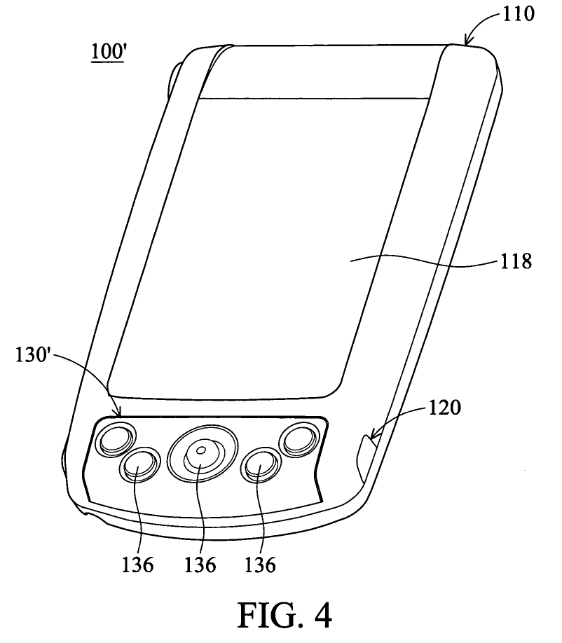

Referring to FIGS. 3A, 3B, and 4, the electronic device 100′ comprises a main body 110, two separating members 120, and a replaceable module 130′. The replaceable module 130′, in this embodiment, is a computer operation module.

Referring to FIGS. 3A, 3C, and 3D, the replaceable module 130′ is detachably disposed in the replacement portion 111 and is electrically connected to the main body 110. Two first engaging portions 131 are disposed on two opposite fifth sidewalls 113a′ of the replaceable module 130′, respectively. When the replaceable module 130′ is fixed in the replacement portion 111, the first engaging portions 131 engage the first engaging openings 112. At this point, as shown in FIG. 3E, the pushing elements 123 of the separating members 120 abut the first engaging portions 131 of the replaceable module 130′. Conversely, when the replaceable module 130′ is separated from the replacement portion 111, the button keys 121 of the separating members 120 can be pushed simultaneously. The first engaging portions 131 of the replaceable module 130′ resiliently retract by abutment of the pushing elements 123 and thereby disengage from the first engaging openings 112. The replaceable module 130′ can then be removed from the replacement portion 111.

Moreover, the replaceable module 130′ comprises a second engaging portion 132 disposed on the bottom surface thereof. A second engaging opening 115 is formed on the bottom surface of the replacement portion 111. The second engaging portion 132 has a substantially L-like configuration (same as that in FIG. 1D). Additionally, the replaceable module 130′ comprises a third engaging portion 133 disposed thereon.

As shown in FIG. 3D, the replaceable module 130′ comprises a second signal connection portion 134 disposed on the bottom surface thereof. Similarly, the first signal connection portion 117 disposed on the replacement portion 111 is a spring plate type connector and the second signal connection portion 134 is a metal connector, i.e. edge connector.

When the replaceable module 130′ is fixed on the main body 110, the second engaging portions 132 of the replaceable module 130′ can be inserted into the second engaging opening 115 of the replacement portion 111. The replaceable module 130′ is then pushed horizontally and toward the third engaging opening 116 formed on the third sidewall 119 of the replacement portion 111. Since the second engaging portions 132 have a substantially L-like configuration, the second engaging portions 132 can be engaged in the second engaging opening 115. At this point, the third engaging portion 133 of the replaceable module 130′ can enter and engage the third engaging opening 116. In another aspect, the first engaging portions 131 of the replaceable module 130′ engage the first engaging openings 112 and the first signal connection portion 117 disposed on the replacement portion 111 is electrically connected to the second signal connection portion 134 disposed on the bottom surface of the replaceable module 130′. Two-way signal transmission can thus be performed between the replaceable module 130 and the main body 110.

Conversely, when the replaceable module 130′ is separated from the main body 110, the button keys 121 of the separating members 120 can be pushed simultaneously. The first engaging portions 131 of the replaceable module 130′ resiliently retract by abutment of the pushing elements 123 and thereby disengage from the first engaging openings 112. The replaceable module 130′ is pushed horizontally and outward, such that the third engaging portion 133 thereof is separated from the third engaging opening 116 of the replacement portion 111. The replaceable module 130′ is then taken up, such that the second engaging portions 132 disposed on the bottom surface of the replaceable module 130′ can be separated from the second engaging opening 115 formed on the replacement portion ill. At this point, the replaceable module 130′ is completely removed from the replacement portion 111 or the main body 110 and another replaceable module can instead be fixed in the replacement portion 111 of the main body 110 as required.

Additionally, as shown in FIG. 3B, the replaceable module 130′ comprises a plurality of operational button keys 136 disposed thereon for performing functions of computer or video games.

In conclusion, the replaceable modules illustrated in the aforementioned embodiments are not limited to the operational module for a cellular phone or computer operational module. Namely, the replaceable module may is be a video game module or a digital camera module.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An electronic device, comprising:
a main body, with a replacement portion and at least one first engaging opening, wherein at least one part of the first engaging opening is formed on the replacement portion;
at least one separating member disposed in the main body, wherein at least one part of the separating member passes through the first engaging opening; and
at least one replaceable module, with at least one first engaging portion, wherein the replaceable module is fixed in the replacement portion by the first engaging portion engaging the first engaging opening and separates from the replacement portion by means of the separating member.

2. The electronic device as claimed in claim 1, wherein the separating member further comprises a button key, a resilient element, and an pushing element connected to the button key, the resilient element and pushing element are disposed on one side of the button key, and one end of the pushing element abuts the first engaging portion when the button key is pushed.

3. The electronic device as claimed in claim 2, wherein the resilient element is connected to the button key.

4. The electronic device as claimed in claim 2, wherein the resilient element comprises a spring.

5. The electronic device as claimed in claim 2, wherein the main body further comprises an accommodating portion and a separating wall disposed between the accommodating portion and the replacement portion, the first engaging opening is formed on the separating wall and connects the replacement portion to the accommodating portion, at least one part of the separating member is disposed in the accommodating portion, and one end of the pushing element passes through the first engaging opening to abut the first engaging portion when the button key is pushed.

6. The electronic device as claimed in claim 5, wherein the main body further comprises a housing and an opening formed thereon and connected to the accommodating portion, at least one part of the button key is disposed in the opening, and the resilient and pushing elements are disposed in the accommodating portion.

7. The electronic device as claimed in claim 1, wherein the replacement portion further comprises a first bottom surface, a first sidewall, and a third sidewall, the replaceable module further comprises a second bottom surface, a second sidewall, and a fourth sidewall, and the first bottom surface faces the second bottom surface, the first sidewall faces the second sidewall, and the third sidewall faces the fourth sidewall when the replaceable module is fixed in the replacement portion.

8. The electronic device as claimed in claim 7, wherein the first bottom surface further comprises a second engaging opening, the second bottom surface further comprises a second engaging portion, and the second engaging portion engages the second engaging opening when the replaceable module is fixed in the replacement portion.

9. The electronic device as claimed in claim 7, wherein the third sidewall further comprises a third engaging opening, the fourth sidewall further comprises a third engaging portion, the third engaging portion engages the third engaging opening when the replaceable module is fixed in the replacement portion.

10. The electronic device as claimed in claim 1, wherein the main body further comprises a first signal connection portion, the replaceable module further comprises a second signal connection portion opposing the first signal connection portion, and the first signal connection portion is electrically connected to the second signal connection portion when the replaceable module is fixed in the replacement portion.

11. The electronic device as claimed in claim 1, wherein the replaceable module is an operational module for a cellular phone or a keyboard.

12. The electronic device as claimed in claim 1, wherein the first engaging portion further comprises a resilient arm and a hook, one end of the resilient arm is connected to the replaceable module and the other end is connected to the hook, and the hook engages the first engaging opening when the replaceable module is fixed in the replacement portion.
